(19) United States
(12) Patent Application Publication
(10) Pub. No.: US 2026/0052878 A1
(43) Pub. Date: Feb. 19, 2026

(54) ELECTRONIC DEVICE

(71) Applicant: LG Display Co., Ltd., Seoul (KR)

(72) Inventors: Unsang YU, Paju-si (KR); Jaekyu PARK, Paju-si (KR); Minchul KIM, Paju-si (KR)

(73) Assignee: LG Display Co., Ltd., Seoul (KR)

(21) Appl. No.: 19/275,687

(22) Filed: Jul. 21, 2025

(30) Foreign Application Priority Data
Aug. 14, 2024 (KR) 10-2024-0108830

(51) Int. Cl. H10K 59/65; G09G 3/3266; G09G 3/3275; H10K 59/121; H10K 59/123; H10K 59/124; H10K 59/38; H10K 102/00

(52) U.S. Cl. CPC H10K 59/65; G09G 3/3266; G09G 3/3275; H10K 59/1213; H10K 59/123; H10K 59/124; H10K 59/38; G09G 2310/08; H10K 2102/3026

(57) ABSTRACT

An electronic device in some examples includes a substrate including a display area having display pixels and a non-display area surrounding the display area, a display panel having an organic light-emitting device arranged in the display pixels of the substrate, and an optical device including an image sensing device mounted on the substrate and a logic unit operably connected to the image sensing device. The image sensing device is configured to receive light and generate image data.

### CROSS-REFERENCE TO RELATED APPLICATION

The present application claims priority to Korean Patent Application No. 10-2024-0108830, filed in the Republic of Korea on Aug. 14, 2024, the entire contents of which are hereby expressly incorporated by reference into the present application.

### BACKGROUND

### Field of the Invention

This specification relates to an apparatus and particularly to, for example, without limitation, an electronic device.

### Description of the Related Art

With the advancement of the information society, there is an increasing demand for display devices that can show images, and various types of display devices such as liquid crystal display (LCD) devices and organic light emitting diode (OLED) displays are being utilized.

Among display devices, OLED displays are self-emissive, offering superior viewing angles and contrast ratios compared to LCDs, while eliminating the need for a separate backlight, enabling a lightweight and slim design with advantageous power consumption. Furthermore, OLED displays support low-voltage DC operation, feature fast response times, and, most notably, offer the advantage of lower manufacturing costs.

Recently, there has been a growing demand for OLED displays that cater to the needs of augmented reality (AR), virtual reality (VR), and ultra-high-resolution display devices of comparable quality.

The description provided in the discussion of the related art section should not be assumed to be prior art merely because it is mentioned in or associated with that section. The discussion of the related art section can include information that describes one or more aspects of the subject technology, and the description in this section does not limit the invention.

### SUMMARY OF THE DISCLOSURE

Other systems, methods, features and advantages will be, or will become, apparent to one with skill in the art upon examination of the following figures and detailed description. It is intended that all such additional systems, methods, features and advantages be included within this description, be within the scope of the present disclosure. Further aspects and advantages are discussed below in conjunction with embodiments of the disclosure.

It is an object of the present disclosure to provide an electronic device that achieves compactness by integrating an optical device into a display panel.

It is another object of the present disclosure to provide an electronic device with a reduced number of components by integrating an optical device into a display panel.

It is still another object of the present disclosure to provide an electronic device capable of adjusting the brightness of the display panel based on a user's gaze position detected by an optical device.

The objects of the present disclosure are not limited to the aforementioned, and other technical objectives can be inferred from the following embodiments of the present disclosure.

In order to accomplish the above objects, an electronic device according to one or more embodiments of the present disclosure includes a substrate including a display area including display pixels and a non-display area surrounding the display area, a display panel including an organic light-emitting device arranged in the display pixels of the substrate, and an optical device including an image sensing device mounted on the substrate and being configured to receive light and generate image data, and a logic unit operably connected to the image sensing device.

In order to accomplish the above objects, an electronic device according to another embodiment of the present disclosure includes a substrate including a display area including display pixels and a non-display area surrounding the display area, a display panel including an organic light-emitting device arranged on the substrate, and an optical device including a first chip including an image sensing device configured to receive light and generate image data, and a second chip operably connected to the image sensing device and distinct from the first chip, wherein the first chip and the second chip are each mounted on the substrate.

The specific details of other embodiments of the present disclosure are included in the detailed description and drawings.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram illustrating a display device according to one or more embodiments of the present disclosure;

FIG. 2 is a plan view of an electronic device according to one or more embodiments of the present disclosure;

FIG. 3 is a plan view of a display panel according to an embodiment of the present disclosure;

FIG. 4 is a cross-sectional view taken along line A-A′ of FIG. 3.

FIG. 5 is a cross-sectional view taken along line B-B′ of FIG. 3;

FIG. 6 is a cross-sectional view of the organic light-emitting device in FIG. 4.

FIG. 7 is a cross-sectional view of the organic light-emitting device as an alternative embodiment to that of FIG. 6;

FIG. 8 is a perspective view of the optical device according to an embodiment of the present disclosure;

FIG. 9 is a detailed view of the optical device of FIG. 8;

FIG. 10 is a detailed view of the image sensing device in FIG. 9;

FIG. 11 is a cross-sectional view taken along C-C′ of FIG. 2 and D-D′ lines of FIG. 8;

FIG. 12 is a perspective view of the optical device according to another embodiment of the present disclosure;

FIG. 13 is a detailed view of the optical device of FIG. 12;

FIG. 14 is a schematic diagram illustrating the generation of user gaze position data through the optical device according to another embodiment of the present disclosure;

FIG. 15 is a schematic diagram illustrating the generation and provision of user gaze position data according to another embodiment of the present disclosure;

FIG. 16 is a cross-sectional view of the display panel and image sensing device of the electronic device according to another embodiment of the present disclosure; and

FIG. 17 is a plan view of the electronic device according to another embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments can be provided so that this disclosure can be sufficiently thorough and complete to assist those skilled in the art to fully understand the scope of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

Any implementation described herein as an “example” is not necessarily to be construed as preferred or advantageous over other implementations.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, embodiments are described with reference to accompanying drawings. In the specification, when a component (or area, layer, part, etc.) is mentioned as being “on top of,” “connected to,” or “coupled to” another component, it means that it can be directly connected/coupled to the other component, or a third component can be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc. are used to describe various components, but the components should not be limited by these terms. The terms are used only for distinguishing one component from another component and may not define order or sequence. For example, a first component can be referred to as a second component and, similarly, the second component can be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example, consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments of the present disclosure can be provided so that this disclosure can be sufficiently thorough and complete to assist those skilled in the art to fully understand the scope of the present disclosure.

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship. All the components of each electronic device according to all embodiments of the present disclosure are operatively coupled and configured.

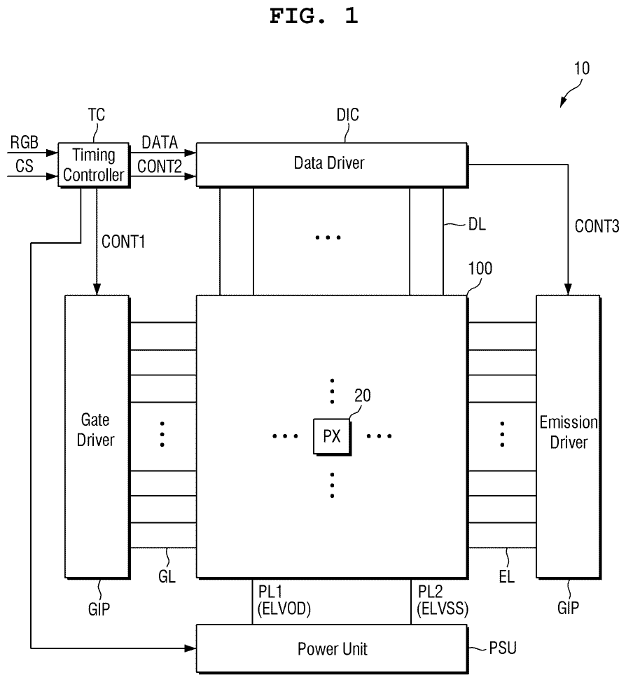

FIG. 1 is a block diagram illustrating a display device or an electronic device according to an embodiment of the present disclosure.

Referring to FIG. 1, an electronic device 10 includes a timing controller TC, a gate driver GIP, a data driver DIC (driver integrated circuit), an emission driver GIP, a power unit PSU, and a display panel 100. The timing controller TC, gate driver GIP, data driver DIC, emission driver GIP, power unit PSU, and display panel 100 can be interpreted as components that constitute a display device.

The timing controller TC can receive video signals RGB and control signals CS from external host systems or the like. The video signals RGB can include a plurality of grayscale data. The control signals CS can include a horizontal sync signal, a vertical sync signal, and a main clock signal.

The timing controller TC processes the video signals RGB and control signals CS to suit the operating conditions of the display panel 100, and it can generate and output image data DATA, a gate driving control signal CONT1, a data driving control signal CONT2, an emission driving control signal CONT3, and a power supply control signal CONT4.

The gate driving control signal CONT1 can include scan timing control signals such as gate start pulse, gate shift clock, and gate output enable signals, and the data driving control signal CONT2 can include data timing control signals such as source sampling clock, polarity control, and source output enable signals.

The gate driver GIP, in response to the gate control signal CONT1 received from the timing controller TC, can sequentially output gate signals through the gate lines GL within one horizontal period. Accordingly, the pixel rows connected to each gate line GL can be turned on in one horizontal period. During one horizontal period, data signals can be applied to the turned-on pixel rows through the gate lines GL.

The gate driver GIP can be composed of stage circuits connected respectively to a plurality of gate lines GL and can be mounted on the display panel 100 in the form of Gate in Panel (GIP). The gate driver GIP can include shift registers, level shifters, or the like.

The data driver DIC can convert the digital image data DATA received from the timing controller TC into analog data signals according to the data driving control signal CONT2. The data driver DIC can apply the analog data signals to corresponding panel pixels 20 through the data lines DL.

The emission driver GIP can generate emission signals based on the emission driving control signal CONT3 outputted from the timing controller TC. The emission driver 40 can supply the generated gate signals to the panel pixels 20 through a plurality of emission lines EL.

In FIG. 1, the gate driver and emission driver are shown as separate components, but they can be integrated. Hereafter, the gate driver and emission driver are referred to collectively as the gate driver GIP.

The power unit PSU can convert the voltage input from an external source, based on the power supply control signal CONT4 into a high voltage ELVDD and a low voltage ELVSS that are standard voltages for use in the electronic device 10. The power unit PSU outputs the generated driving voltages ELVDD and ELVSS to the components through power lines PL1 and PL2.

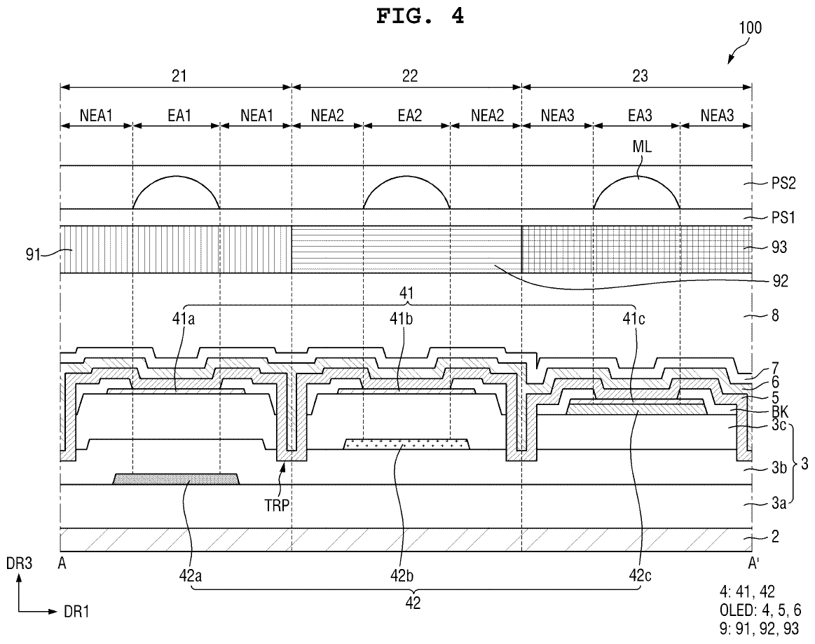

According to an embodiment of the electronic device 10, the timing controller TC, data driver DIC, gate driver GIP, and power unit PSU can each be integrated into the display panel 100. For example, during the process of forming the display panel 100, the circuits constituting the timing controller TC, data driver DIC, gate driver GIP, and power unit PSU can be formed together. The timing controller TC, data driver DIC, gate driver GIP, and power unit PSU can each be mounted on a substrate 2 (see FIG. 4). In some embodiments of the present disclosure, the timing controller TC, data driver DIC, gate driver GIP, and power unit PSU can be implemented as separate chips, distinct from the display panel 100.

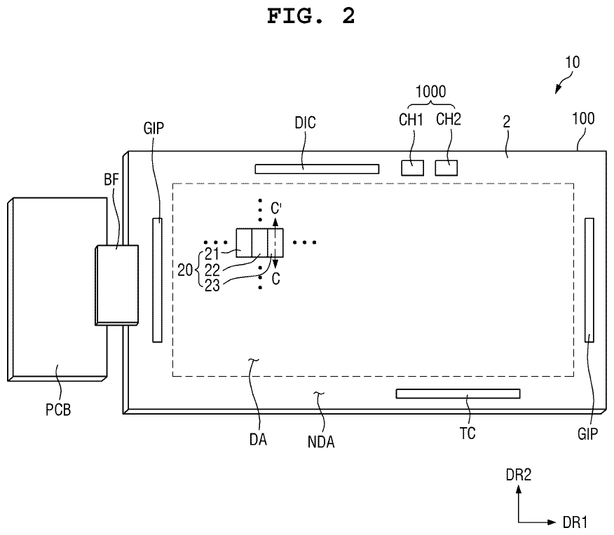

FIG. 2 is a plan view of an electronic device according to an embodiment of the present disclosure.

Referring to FIGS. 1 and 2, the electronic device 10 can include the components described above in FIG. 1. The detailed descriptions of the components provided with reference to FIG. 1 will be omitted with FIG. 2.

The electronic device 10 can include a display panel 100, a connection film BF, a printed circuit board PCB, and an optical device 1000. The display panel 100, connection film BF, and printed circuit board PCB can be collectively referred to as the display device, but the embodiments of the present disclosure are not limited thereto.

The display panel 100 includes a substrate 2 and can have a display area DA and a non-display area NDA surrounding the display area DA. The display area DA can include a plurality of panel pixels 20. Each of the plurality of panel pixels 20 can include a plurality of panel sub-pixels 21, 22, and 23.

In the non-display area NDA, the timing controller TC, gate driver GIP, and data driver DIC can be arranged. The timing controller TC, gate driver GIP, and data driver DIC are mounted on the substrate 2 and can be embedded within the display panel 100; however, the embodiments of the present disclosure are not limited thereto.

The printed circuit board PCB can be connected to the display panel 100 via the connection film BF.

The optical device 1000 can include a plurality of chips CH1 and CH2. The first chip CH1 can include an image sensing device, and the second chip CH2 can include a logic unit; however, the embodiments of the present disclosure are not limited thereto. The first chip CH1 and the second chip CH2 can be separately arranged. For example, the chips CH1 and CH2 can be placed in the non-display area NDA of the display panel 100 and can have a structure embedded within the display panel 100. The chips CH1 and CH2 can be mounted on the substrate 2 of the display panel 100.

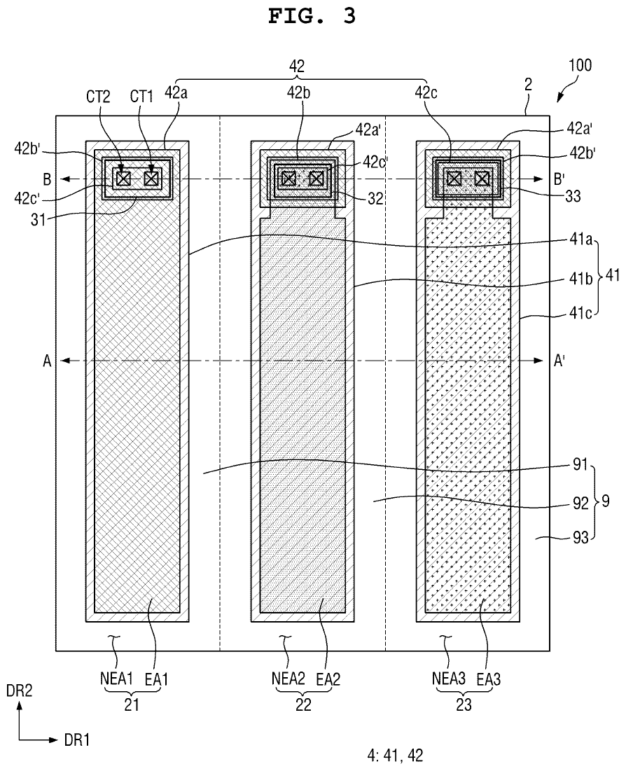

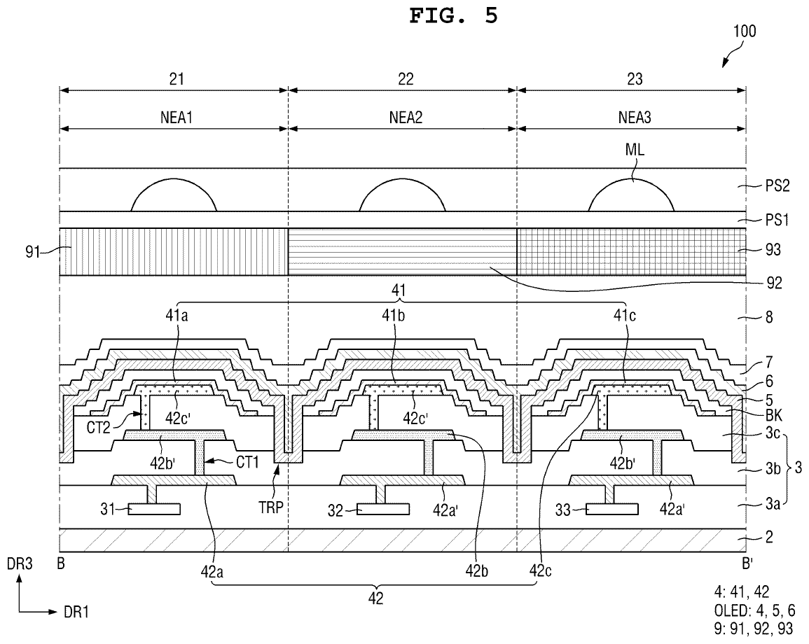

FIG. 3 is a plan view of a display panel according to an embodiment of the present disclosure. FIG. 4 is a cross-sectional view taken along line A-A′ of FIG. 3. FIG. 5 is a cross-sectional view taken along line A-A′ of FIG. 3.

Referring to FIGS. 3 to 5, the display panel 100 according to an embodiment of the present disclosure includes a substrate 2, a first electrode 4, a common light-emitting layer 5, and a cathode electrode 6.

A plurality of panel sub-pixels 21, 22, and 23 are formed on the substrate 2. The plurality of panel sub-pixels 21, 22, and 23 can constitute a single panel pixel. A plurality of panel pixels can be formed on the substrate 2.

The plurality of panel sub-pixels 21, 22, and 23 includes the first panel sub-pixel 21, the second panel sub-pixel 22, and the third panel sub-pixel 23. By arranging the first panel sub-pixel 21, the second panel sub-pixel 22, and the third panel sub-pixel 23 in order, the second panel sub-pixel 22 can be adjacent to one side of the first panel sub-pixel 21, for example, on the left, and the third panel sub-pixel 23 can be adjacent to one side of the second panel sub-pixel 22, for example, on the left.

Throughout this specification, the phrase “two panel sub-pixels are arranged adjacent to each other” should be interpreted to mean that no other panel sub-pixel is placed between the two panel sub-pixels.

The first panel sub-pixel 21 can be configured to emit red (R) light, the second panel sub-pixel 22 can be configured to emit green (G) light, and the third panel sub-pixel 23 can be configured to emit blue (B) light, although this is not necessarily limited to these colors.

In FIG. 3, the panel pixel is shown as including only three panel sub-pixels 21, 22, and 23, but it is not limited to this configuration, and the panel pixel can include four panel sub-pixels. When the panel pixel includes four panel sub-pixels, a fourth panel sub-pixel configured to emit white (W) light can be further included.

The first to third panel sub-pixels 21, 22, and 23 can each be configured with the same or substantially same size. For example, the first to third panel sub-pixels 21, 22, and 23 can each be configured to have the same or substantially same width and height. Here, the width can refer to the horizontal direction (first direction DR1) based on FIG. 3, and the height can refer to the direction perpendicular to the width (second direction DR2) based on FIG. 3, though the embodiments of this disclosure are not limited thereto.

Each panel sub-pixel 21, 22, and 23 can include an emissive area (EA1, EA2, EA3) and a non-emissive area (NEA1, NEA2, NEA3). The first panel sub-pixel 21 can include a first emissive area EA1 and a first non-emissive area NEA1 surrounding the first emissive area EA1, the second panel sub-pixel 22 can include a second emissive area EA2 and a second non-emissive area NEA2 surrounding the second emissive area EA2, and the third panel sub-pixel 23 can include a third emissive area EA3 and a third non-emissive area NEA3 surrounding the third emissive area EA3. The emissive areas EA1, EA2, and EA3 can be the same or substantially same as the areas exposed from the bank BK of the anode electrodes 41a, 41b, and 41c, which will be described later.

The anode electrode 4 is patterned for each individual panel sub-pixel 21, 22, and 23. For example, a first electrode 4 is formed in the first panel sub-pixel 21, another first electrode 4 is formed in the second panel sub-pixel 22, and yet another first electrode 4 is formed in the third panel sub-pixel 23. The first electrode 4 can function as the positive electrode of the display panel 100. The first electrode 4 can include a reflective electrode and an anode electrode. The anode electrode 41 and the reflective electrode 42 can be arranged for each panel sub-pixel 21, 22, and 23. The anode electrode 41 includes a first anode electrode 41a disposed in the first panel sub-pixel 21, a second anode electrode 41b disposed in the second panel sub-pixel 22, and a third anode electrode 41c disposed in the third panel sub-pixel 23, while the reflective electrode 42 can include a first reflective electrode 42a disposed in the first panel sub-pixel 21, a second reflective electrode 42b disposed in the second panel sub-pixel 22, and a third reflective electrode 42c disposed in the third panel sub-pixel 23.

A bank BK (FIG. 4), which will be described later, can be disposed on each anode electrode 41a, 41b, and 41c. The bank BK is configured to cover the edges of the anode electrodes 41a, 41b, and 41c that are disposed in the first to third panel sub-pixels 21, 22, and 23, thereby allowing the first panel sub-pixel 21, second panel sub-pixel 22, and third panel sub-pixel 23 to be separated.

The display panel 100 can further enhance light extraction efficiency by utilizing microcavity characteristics through reflective electrodes 42a, 42b, and 42c, which have different surface heights for each panel sub-pixel 21, 22, and 23.

The micro-cavity characteristic refers to the phenomenon where constructive interference occurs and light is amplified when the distance between the reflective electrodes 42a, 42b, and 42c and the cathode electrode 6 is an integer multiple of the half-wavelength (λ/2) of the light emitted from the panel sub-pixels 21, 22, and 23, and the reflection and re-reflection processes between the reflective electrodes 42a, 42b, and 42c and the cathode electrode 6 continue to amplify the light, thereby continuously enhancing the external light extraction efficiency.

The common light-emitting layer 5 can be configured to emit white light. For example, the common light-emitting layer 5 can be configured as a 2-stack structure including a blue light-emitting layer, a yellow-green light-emitting layer, and a charge generation layer, or as a 3-stack structure including a blue light-emitting layer, a green light-emitting layer, a red light-emitting layer, and a charge generation layer to emit white light, but is not limited to these configurations and can be provided with a plurality of layers exceeding three stacks as possible as it is capable of emitting white light.

The common light-emitting layer 5 can be formed as a common layer extending across the entire first to third panel sub-pixels 21, 22, and 23.

The cathode electrode 6 is configured to form an electric field with the anode electrodes 41a, 41b, and 41c and can function as a cathode. The cathode electrode 6 is disposed on the upper surface of the common light-emitting layer 5, opposite to the lower surface where the anode electrodes 41a, 41b, and 41c are in contact, and can be provided as a common layer extending across the entire first to third panel sub-pixels 21, 22, and 23.

In the case of a top emission configuration, the cathode electrode 6 can be provided as a second electrode, but in the case of a bottom emission method, it can be provided as a first electrode including a reflective material. In the case of a top emission configuration, the cathode electrode 6 can be formed as a semi-transparent electrode to enhance light extraction efficiency using micro-cavity characteristics. The display panel 100 utilizes micro-cavity characteristics in the top emission configuration to improve light extraction efficiency, which is why the cathode electrode 6 is formed as a semi-transparent electrode, as an example.

The color filter layer 9 is provided on each of the first to third panel sub-pixels 21, 22, and 23 to block predetermined colors from the light emitted by the common light-emitting layer 5 of each panel sub-pixel 21, 22, and 23. The first panel color filter 91 provided in the first panel sub-pixel 21 can be configured to block all colors except for red (R) light. In this case, the first panel color filter 91 can be a red color filter. The second panel color filter 92 provided in the second panel sub-pixel 22 can be configured to block all colors except for green (G) light. In this case, the second panel color filter 92 can be a green color filter. The third panel color filter 93 provided in the third panel sub-pixel 23 can be configured to block all colors except for blue (B) light. In this case, the third panel color filter 93 can be a blue color filter. However, the embodiments of the present disclosure are not limited thereto.

The first to third panel color filters 91, 92, and 93 provided in each of the first to third panel sub-pixels 21, 22, and 23 can be configured to have the same or substantially same size as the respective panel sub-pixels or can be scaled up or down by a certain ratio of the size of each panel sub-pixel.

Transistors 31, 32, and 33 can be disposed in the non-emissive areas NEA1, NEA2, and NEA3 of each panel sub-pixel 21, 22, and 23. For example, transistors 31, 32, and 33 can overlap with the reflective electrodes 42a, 42b, and 42c disposed in each panel sub-pixel 21, 22, and 23. Transistors 31, 32, and 33 can be electrically connected to the reflective electrodes 42a, 42b, and 42c.

Hereinafter, a detailed description of the stacked structure of the display panel 100 according to an embodiment of the present disclosure is provided.

The display panel 100 according to an embodiment of the present disclosure includes a substrate 2, an insulating layer 3, a first electrode 4, a bank BK, a common light-emitting layer 5, a cathode electrode 6, a capping layer 7, an encapsulation layer 8, and a color filter layer 9.

The substrate 2 can be made of a semiconductor material such as plastic film, glass substrate, or silicon.

The substrate 2 can be made of transparent or opaque materials. On the substrate 2, the first panel sub-pixel 21, the second panel sub-pixel 22, and the third panel sub-pixel 23 are provided. The first panel sub-pixel 21 can emit red (R) light, the second panel sub-pixel 22 can emit blue (B) light, and the third panel sub-pixel 23 can emit green (G) light.

In an embodiment of the present disclosure, the display panel 100 is configured in a so-called top emission method where the emitted light is released upwards, and therefore, the material of the substrate 2 can be either a transparent material or an opaque material. On the upper side of the first to third panel sub-pixels 21, 22, and 23, panel color filters 91, 92, and 93 can be provided to transmit light of the respective colors as mentioned above.

The insulating layer 3 is formed on the substrate 2. The insulating layer 3 can include an inorganic insulating material. The insulating layer 3 can include a first insulating layer 3a, a second insulating layer 3b on the first insulating layer 3a, and a third insulating layer 3c on the second insulating layer 3b.

The insulating layer 3 includes circuit elements such as multiple thin-film transistors 31, 32, and 33, various signal lines, and capacitors, provided for each panel sub-pixel 21, 22, and 23. The first insulating layer 3a can have thin-film transistors 31, 32, and 33 arranged therein. The signal lines can include gate lines, data lines, power lines, and reference lines, and the thin-film transistors 31, 32, and 33 can include switching thin-film transistors, driving thin-film transistors, and sensing thin-film transistors. Each of the panel sub-pixels 21, 22, and 23 is defined by the intersection structure of the gate lines and data lines. The insulating layer 3 can surround the thin-film transistors 31, 32, and 33.

The switching thin-film transistor switches according to the gate signal supplied to the gate line to supply the data voltage from the data line to the driving thin-film transistor.

The driving thin-film transistor switches according to the data voltage supplied from the switching thin-film transistor, generating data current from the power supplied through the power line, which is then supplied to the first electrode 4.

The sensing thin-film transistor senses the threshold voltage variation of the driving thin-film transistor, which causes image quality degradation, and in response to the sensing control signal supplied from the gate line or a separate sensing line, it supplies the current from the driving thin-film transistor to the reference line.

The capacitor serves to maintain the data voltage supplied to the driving thin-film transistor for one frame and is connected to the gate terminal and source terminal of the driving thin-film transistor, respectively.

The first thin-film transistor 31, second thin-film transistor 32, and third thin-film transistor 33 are disposed in the first insulating layer 3a for each panel sub-pixel 21, 22, 23. The first thin-film transistor 31 is connected to the first electrode 4 disposed on the first panel sub-pixel 21, thereby applying a driving voltage to emit light of the corresponding color for the first panel sub-pixel 21. The first thin-film transistor 31, second thin-film transistor 32, and third thin-film transistor 33 can be located in the same thin-film transistor layer, but the embodiments of the present disclosure are not limited to this.

The second thin-film transistor 32 is connected to the first electrode 4 disposed on the second panel sub-pixel 22, thereby applying a driving voltage to emit light of the corresponding color for the second panel sub-pixel 22.

The third thin-film transistor 33 is connected to the anode electrode 41 disposed on the third panel sub-pixel 23, thereby applying a driving voltage to emit light of the corresponding color for the third panel sub-pixel 23.

The first panel sub-pixel 21, second panel sub-pixel 22, and third panel sub-pixel 23 each supply a predetermined current to the light-emitting layer according to the data voltage of the data line when a gate signal is input from the gate line, using their respective transistors 31, 32, and 33. As a result, the light-emitting layers of the first panel sub-pixel 21, second panel sub-pixel 22, and third panel sub-pixel 23 can emit light at a predetermined brightness according to the supplied current.

The insulating layer 3 can protect the transistors 31, 32, and 33. The insulating layer 3 can be made of an inorganic insulating material, but it is not limited to this, and can also be made of an organic insulating material. For example, the insulating layer 3 can be made of an inorganic material such as silicon nitride (SiNx), silicon oxide (Siox), or aluminum oxide (Al₂O₃), but the embodiments of the present disclosure are not limited to these materials. The first insulating layer 3a, the second insulating layer 3b, and the third insulating layer 3c can be made of inorganic materials such as silicon nitride (SiNx), silicon oxide (SiOx), or aluminum oxide (Al₂O₃), but the embodiments of the present disclosure are not limited thereto.

A plurality of reflective electrode layers can be arranged on the insulating layer 3. The reflective electrode layers can include a first reflective electrode layer on the first insulating layer 3a, a second reflective electrode layer on the second insulating layer 3b, and a third reflective electrode layer on the third insulating layer 3c. The first reflective electrode layer can include a first reflective electrode 42a and a first connection electrode 42a′, the second reflective electrode layer can include a second reflective electrode 42b and a second connection electrode 42b′, and the third reflective electrode layer can include a third reflective electrode 42c and a third connection electrode 42c′. The first reflective electrode 42a and the first connection electrode 42a′ can be arranged in the same layer and can include the same material. The second reflective electrode 42b and the second connection electrode 42b′ can be arranged in the same layer and can include the same material. The third reflective electrode 42c and the third connection electrode 42c′ can be arranged in the same layer and can include the same material.

Each reflective electrode layer can include a reflective material to reflect light. For example, the reflective material can be metal, but it is not limited to this, and any other material capable of reflecting light can also be used. For example, the reflective material can include aluminum (Al) or silver (Ag), but the embodiments of the present disclosure are not limited to these.

The reflective electrode 42 is disposed at a relatively lower position than the common light-emitting layer 5, allowing reflection of the light emitted from the common light-emitting layer 5 upwards. Here, the upward direction refers to the direction in which the user perceives the light, which may, for example, be the side where the encapsulation layer 8 or the color filter layer 9 is disposed. As a result, the first panel sub-pixel 21, second panel sub-pixel 22, and third panel sub-pixel 23 can achieve higher light efficiency compared to when the reflective electrode 42 is not present, and the user can perceive a high luminance through the improved light efficiency. For example, a clear image can be perceived.

The first reflective electrode 42a in the first emissive area EA1 and the first non-emissive area NEAL of the first panel sub-pixel 21 is disposed on the first insulating layer 3a, the second reflective electrode 42b in the second emissive area EA2 and the second non-emissive area NEA2 of the second panel sub-pixel 22 is disposed on the first insulating layer 3a, and the third reflective electrode 42c in the third emissive area EA3 and the third non-emissive area NEA3 of the third panel sub-pixel 23 can be disposed on the first insulating layer 3a. In each non-emissive area NEA1, NEA2, and NEA3, the first reflective electrode 42a and the first connection electrode 42a′ can be electrically connected to each transistor 31, 32, and 33.

On top of the first reflective electrode 42a and the first connection electrode 42a′, the second insulating layer 3b can be disposed.

On the second insulating layer 3b, the second reflective electrode 42b and the second connection electrode 42b′ can be disposed. The second reflective electrode 42b is disposed in the second panel sub-pixel 22, and the second connection electrode 42b′ can be disposed in the first and third panel sub-pixels 21 and 23, respectively. The second reflective electrode 42b can be connected to the first connection electrode 42a′ in the second non-emissive area NEA2 of the second panel sub-pixel 22 through the first contact hole CT1. The second connection electrode 42b′ can be connected to the first reflective electrode 42a and the first connection electrode 42a′ in the non-emissive areas NEA1 and NEA3, respectively, through the first contact hole CT1.

On the second reflective electrode 42b and the second connection electrode 42b′, the third insulating layer 3c can be disposed.

On the third insulating layer 3c, the third reflective electrode 42c and the third connection electrode 42c′ can be disposed. The third reflective electrode 42c is disposed in the third panel sub-pixel 23, and the third connection electrode 42c′ can be disposed in the first and second panel sub-pixels 21 and 22, respectively. The third reflective electrode 42c can be connected to the second connection electrode 42b′ in the third non-emissive area NEA3 of the third panel sub-pixel 23 through the second contact hole CT2. The third connection electrode 42c′ can be connected to the second connection electrode 42b′ and the second reflective electrode 42b in the non-emissive areas NEA1 and NEA2, respectively, through the second contact hole CT2.

A trench section TRP can be formed in the insulating layer 3. For example, the trench section TRP can be formed in the non-emissive areas NEA1, NEA2, and NEA3. As shown in FIG. 4 and FIG. 5, the trench section TRP can be formed by penetrating parts of the third insulating layer 3c and the second insulating layer 3b, but the embodiments of the present disclosure are not limited to this. According to the display panel 100 of an embodiment of the present disclosure, since a trench section TRP is formed between adjacent panel sub-pixels 21, 22, and 23, lateral leakage current LLC in the common light-emitting layer 5 between adjacent panel sub-pixels 21, 22, and 23 can be improved.

As shown in FIG. 5, in the emission areas EA1, EA2, and EA3, the distance between the reflective electrodes 42a, 42b, and 42c and the cathode electrode 6 can differ from each other. For example, the distance between the first reflective electrode 42a and the cathode electrode 6 can be the largest, followed by the distance between the second reflective electrode 42b and the cathode electrode 6, with the distance between the third reflective electrode 42c and the cathode electrode 6 being the smallest.

In this way, the reflective electrodes 42a, 42b, and 42c are formed at various distances (or resonant distances) from the cathode electrode 6 because, depending on the spacing, the reflection and re-reflection between the reflective electrodes 42a, 42b, 42c and the cathode electrode 6 can enhance the light extraction efficiency of different colors of light. Therefore, in the first panel sub-pixel 21, the light extraction efficiency of red light can be improved, in the second panel sub-pixel 22, the light extraction efficiency of green light can be improved, and in the third panel sub-pixel 23, the light extraction efficiency of blue light can be improved.

The anode electrode 41 can include the first anode electrode 41a of the first panel sub-pixel 21, the second anode electrode 41b of the second panel sub-pixel 22, and the third anode electrode 41c of the third panel sub-pixel 23. The anode electrodes 41a, 41b, and 41c can be disposed in the anode electrode layer, positioned in the same layer, and can include the same material.

In the third emissive area EA3 of the third panel sub-pixel 23, the third anode electrode 41c can be directly disposed on the third reflective electrode 42c. In each of the non-emissive area NEA1, NEA2, and NEA3 of the first to third panel sub-pixels 21 to 23, the anode electrodes 41a, 41b, and 41c can be directly disposed on the third connection electrode 42c′ and the third reflective electrode 42c.

Each of the anode electrodes 41a, 41b, and 41c can be electrically connected with the thin-film transistors 31, 32, and 33 in each non-emissive area NEA1, NEA2, and NEA3.

The anode electrodes 41a, 41b, and 41c can include materials with high light transmittance. For example, the anode electrodes 41a, 41b, and 41c can include ITO, IZO, or TiN, but are not limited thereto.

A bank BK can be disposed on the anode electrodes 41a, 41b, and 41c. The bank BK can be made of inorganic materials such as silicon nitride (SiNx), silicon oxide (Siox), or aluminum oxide (Al₂O₃), but the embodiments of the present disclosure are not limited to these materials. The bank BK can be disposed in the non-emissive areas NEA1, NEA2, and NEA3.

In the emissive areas EA1, EA2, and EA3, the bank BK can expose the upper surface of the anode electrodes 41a, 41b, and 41c to define the emissive areas EA1, EA2, and EA3. As shown in FIG. 4, the bank BK can be in contact with the upper surface and the side surface of the anode electrodes 41a, 41b, and 41c. As shown in FIG. 5, in the non-emissive areas NEA1, NEA2, NEA3, the bank BK can cover the entire upper surface of the anode electrodes 41a, 41b, and 41c, but the embodiments of the present specification are not limited thereto.

The common light-emitting layer 5 is formed on the anode electrodes 41a, 41b, 41c and the bank BK. The common light-emitting layer 5 can contact the upper surface of the anode electrodes 41a, 41b, 41c. The common light-emitting layer 5 can directly contact the upper surface of the anode electrodes 41a, 41b, 41c, the upper and side surfaces of the bank BK, and the upper surface of the insulating layer 3. The common light-emitting layer 5 can also extend into the trench part TRP.

According to one embodiment of the present disclosure, the organic light-emitting device OLED can include the first electrode 4, ANO, the cathode electrode 6, CAT, and the common light-emitting layer 5 between the first electrode 4 and the cathode electrode 6.

The common light-emitting layer 5 can be configured to emit white (W) light. To achieve this, the common light-emitting layer 5 can include a plurality of stacks that emit light of different colors. Specifically, the common light-emitting layer 5 can include a first stack, a second stack, and a charge generation layer CGL disposed between the first stack and the second stack.

The cathode electrode 6 is formed on the common light-emitting layer 5. The cathode electrode 6 can function as the cathode of the display panel 100. The cathode electrode 6, like the common light-emitting layer 5, is formed in each of the panel sub-pixels 21, 22, and 23, as well as therebetween.

In an embodiment of the present disclosure, the display panel 100 can have a cathode electrode 6 made of a semi-transparent electrode to implement white light with high light efficiency in the top emission configuration. As a result, micro cavity effects can be obtained for each of the first to third panel sub-pixels 21, 22, and 23. The micro cavity effect can be achieved by repeated reflection and re-reflection of light between the cathode electrode 6 and the reflective electrode 42, which improves light extraction efficiency.

Meanwhile, since the cathode electrode 6 is formed on the upper surface of the common light-emitting layer 5, it can be shaped according to the profile of the common light-emitting layer 5. Since the common light-emitting layer 5 is formed following the profile of the first electrode 4 in the light-emitting region, the cathode electrode 6 can ultimately be formed to follow the profile of the first electrode 4. Additionally, the capping layer 7 on the cathode electrode 6 can also be formed to follow the profile of the cathode electrode 6.

The capping layer 7 can be made of an inorganic insulating material, but is not limited thereto. The capping layer 7 can be disposed on the cathode electrode 6 to protect the organic light-emitting device (OLED).

The encapsulation layer 8 is formed on the cathode electrode 6 to prevent or reduce external moisture from penetrating into the common light-emitting layer 5. This encapsulation layer 8 can be made of an inorganic insulating material or can be formed in an alternating stack structure of inorganic and organic insulating materials, but is not limited to these configurations.

The color filter layer 9 is formed on the encapsulation layer 8. The color filter layer 9 can include a first panel color filter 91 of red (R) provided in the first panel sub-pixel 21, a second panel color filter 92 of green (G) provided in the second panel sub-pixel 22, and a third panel color filter 93 of blue (B) provided in the third panel sub-pixel 23, but is not limited to these configurations.

A first passivation layer PS1 can be disposed on the color filter layer 9, a panel light-concentrating pattern ML can be disposed on the first passivation layer PS1, and a second passivation layer PS2 can be disposed on the panel light-concentrating pattern ML.

The first passivation layer PS1 can be disposed on the color filter layer 9. The material of the first passivation layer PS1 can be the same as at least one of the materials exemplified in the aforementioned insulating layer 3, but the embodiments of the present specification are not limited thereto.

The panel light-concentrating pattern ML can be disposed on the first passivation layer PS1. The panel light-concentrating pattern ML can be provided in plural, and the plurality of panel light-concentrating patterns ML can be disposed in each of the emissive areas EA1, EA2, and EA3. However, the display panel 100 according to an embodiment of the present disclosure is not limited thereto, and the panel light-concentrating pattern ML can also be extended into the non-emissive areas NEA1, NEA2, and NEA3.

The second passivation layer PS2 can be disposed on the panel light-concentrating pattern ML. The material of the second passivation layer PS2 can be the same as at least one of the materials exemplified in the aforementioned insulating layer 3, but the embodiments of the present specification are not limited thereto.

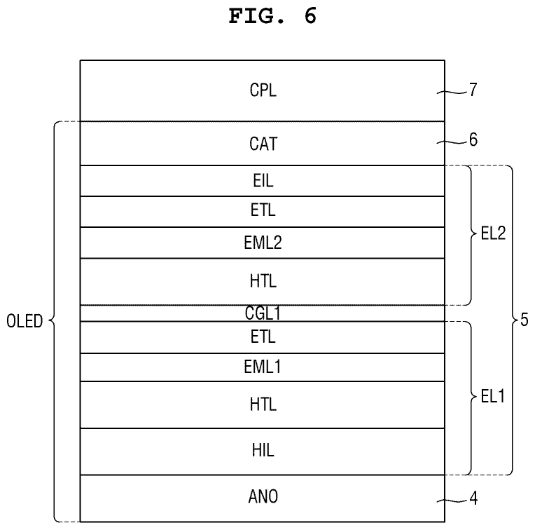

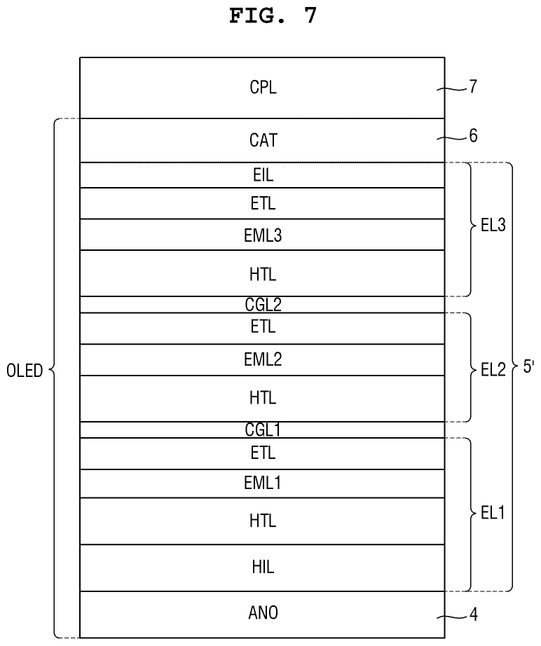

FIG. 6 is a cross-sectional view of the organic light-emitting device in FIG. 4. FIG. 7 is a cross-sectional view of the organic light-emitting device as an alternative embodiment to that of FIG. 6.

Referring to FIGS. 1 to 6, the common light-emitting layer 5 can include a first stack EL1, a second stack EL2, and a first charge generation layer CGL1 formed on the first electrode 4.

The first stack EL1 is provided on the first electrode 4 and can have a structure where a hole injecting layer HIL, a hole transporting layer HTL, a blue (B) emitting layer EML1, and an electron transporting layer ETL are sequentially stacked.

The first stack EL1 can be disposed between the first panel sub-pixel 21 and the second panel sub-pixel 22, and between the second panel sub-pixel 22 and the third panel sub-pixel 23.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a yellow-green (YG) emitting layer EML2, an electron transporting layer ETL, and an electron injecting layer EIL are sequentially stacked.

The second stack EL2 can be disposed between the first panel sub-pixel 21 and the second panel sub-pixel 22, and between the second panel sub-pixel 22 and the third panel sub-pixel 23.

As a result, the common light-emitting layer 5 can be provided as a common layer over the entire first to third panel sub-pixels 21, 22, and 23, as shown in FIG. 4 and FIG. 5.

As shown in FIG. 7, the common light-emitting layer 5′ of the organic light-emitting device (OLED) according to an embodiment of the present disclosure can include the first stack EL1, the second stack EL2, the third stack EL3, the first charge generation layer CGL1 between the first stack EL1 and the second stack EL2, and the second charge generation layer CGL2 between the second stack EL2 and the third stack EL3, provided on the first electrode 4.

The first stack EL1 is provided on the first electrode 4 and can have a structure where a hole injecting layer HIL, a hole transporting layer HTL, a blue (B) emitting layer EML1, and an electron transporting layer ETL are sequentially stacked.

The first stack EL1 can be disposed between the first panel sub-pixel 21 and the second panel sub-pixel 22, as well as between the second panel sub-pixel 22 and the third panel sub-pixel 23, i.e., on the bank BK.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a green (G) emitting layer EML2, and an electron transporting layer ETL are sequentially stacked.

The second stack EL2 can be disposed between the first panel sub-pixel 21 and the second panel sub-pixel 22, as well as between the second panel sub-pixel 22 and the third panel sub-pixel 23, i.e., on the bank BK.

The second charge generation layer CGL2 serves to supply charge to the second stack EL2 and the third stack EL3. The second charge generation layer CGL2 can include an N-type charge generation layer to supply electrons to the second stack EL2 and a P-type charge generation layer to supply holes to the third stack EL3. The N-type charge generation layer can be made by doping a metal material.

The third stack EL3 is provided on the second stack EL2 and can have a structure where a hole transporting layer HTL, a red (R) emitting layer EML3, an electron transporting layer ETL, and an electron injecting layer EIL are sequentially stacked.

The charge generation layer CGL1 and CGL2 can be disposed between the first panel sub-pixel 21 and the second panel sub-pixel 22, and between the second panel sub-pixel 22 and the third panel sub-pixel 23. In an embodiment of the display panel 100, the common light-emitting layer 5 is disposed between each panel sub-pixel 21, 22, and 23, so when one panel sub-pixel emits light, side leakage current can occur through the charge generation layers CGL1 and CGL2 to adjacent panel sub-pixels 21, 22, and 23, but a trench section TRP can be formed between the panel sub-pixels 21, 22, and 23. Through the trench part TRP, the formation length of the common light-emitting layer 5 at the boundaries of the panel sub-pixels 21, 22, and 23 can be increased, thereby lengthening the current path. As a result, side leakage current can be prevented or reduced. Furthermore, by separating the common light-emitting layer 5 in the trench section TRP, side leakage current can be prevented or reduced in advance.

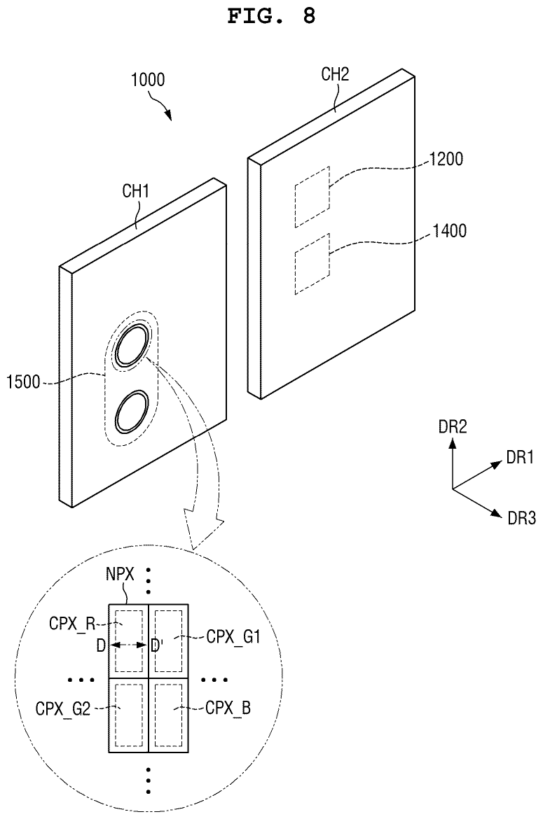

FIG. 8 is a perspective view of the optical device according to an embodiment of the present disclosure.

Referring to FIG. 8, the optical device 1000 can include a first chip CH1 and a second chip CH2 that is distinct from the first chip CH1. The first chip CH1 can include an image sensing device 1500, and the second chip CH2 can include a logic unit 1200 and an input/output interface 1400, but the embodiments of the present disclosure are not limited thereto.

In FIG. 8, the image sensing device 1500 is shown as an example to have two components, but the embodiments of the present disclosure are not limited thereto, and the image sensing device 1500 can include one, three, or more components.

The image sensing device 1500 can include a plurality of image pixels, each of which can include a first pixel, a second pixel, a third pixel, and a fourth pixel. Each pixel can include pixel regions PX_R, PX_G1, PX_G2, PX_B and a peripheral region NPX. It should be noted that the peripheral region NPX of the image sensing device 1500 is distinct from the non-emissive regions NEA1, NEA2, and NEA3 of the panel sub-pixels 21, 22, and 23 mentioned above. The first pixel can be a red pixel that receives red light, the second pixel can be a green pixel that receives green light, the third pixel can be a green pixel that receives green light, and the fourth pixel can be a blue pixel that receives blue light. During the daytime, each pixel can receive light with the corresponding wavelength in the visible light wavelength range.

The structure of the image sensing device 1500 will be described later.

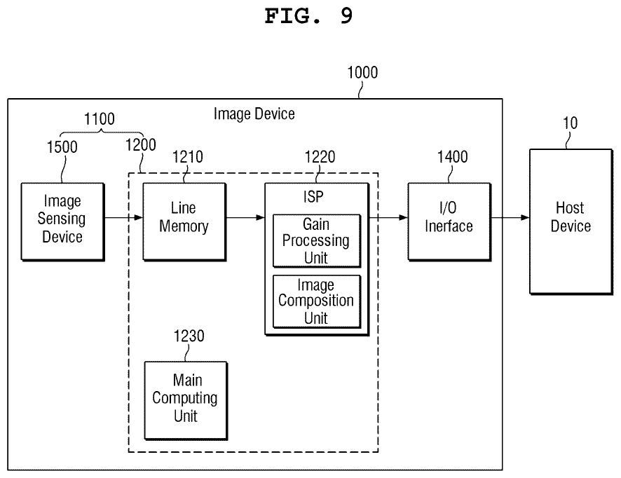

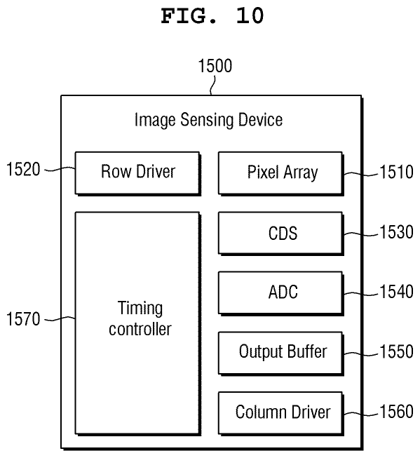

FIG. 9 is a detailed view of the optical device of FIG. 8. FIG. 10 is a detailed view of the image sensing device in FIG. 9.

Referring to FIG. 9, an optical device 1000 according to an embodiment can refer not only to a device such as a digital still camera for capturing still images or a digital video camera for recording videos but also to a device for detecting motion. For example, the optical device 1000 can be implemented as a digital single-lens reflex (DSLR) camera, a mirrorless camera, or a mobile phone (particularly, a smartphone), but is not limited thereto. The optical device 1000 can encompass a device capable of capturing a subject and generating an image by including a lens and an image sensor.

The optical device 1000 can include an image sensing device 1500, a line memory 1210, an image signal processor (ISP) 1220, a main computing unit 1230, and an input/output (I/O) interface 1400. The line memory 1210, the ISP 1220, and the main computing unit 1230 can be included in a logic unit 1200, but the embodiments of the present disclosure are not limited thereto. The image sensing device 1500 and the logic unit 1200 can be referred to as an imaging device, but the embodiments of the present disclosure are not limited thereto.

The image sensing device 1500 can be a complementary metal-oxide-semiconductor image sensor (CIS) that converts optical signals into electrical signals. The overall operation of the image sensing device 1500, including on/off switching, operating modes, operation timing, and sensitivity, can be controlled by the ISP 1220. Under the control of the ISP 1220, the image sensing device 1500 can convert optical signals into electrical signals and transmit the resulting image data to the line memory 1210.

Referring to FIG. 10, the image sensing device 1500 can include a pixel array 1510, row driver 1520, correlated double sampler (CDS) 1530, analog-to-digital converter (ADC) 1540, output buffer 1550, column driver 1560, and timing controller 1570. Here, the components of the image sensing device 1500 are merely examples, and at least some components can be added or omitted as needed.

The pixel array 1510 can include a plurality of image pixels arranged in a plurality of rows and columns. In an embodiment of the present disclosure, the plurality of image pixels can be arranged in a two-dimensional pixel array that includes rows and columns. In another embodiment of the present disclosure, the plurality of image pixels can be arranged in a three-dimensional pixel array. The plurality of image pixels can convert optical signals into electrical signals on a per-pixel basis or per-pixel-group basis, and the image pixels within a pixel group can share at least certain internal circuits. The pixel array 1510 can receive pixel control signals, including a row selection signal, a pixel reset signal, and a transmission signal, from the row driver 1520, and based on these pixel control signals, the corresponding image pixels in the pixel array 1510 can be activated to perform operations corresponding to the row selection signal, pixel reset signal, and transmission signal. Each image pixel can detect incident light by generating photocharges corresponding to the intensity (or illuminance) of the incident light and producing an electrical signal proportional to the amount of generated photocharges.

The row driver 1520 can activate the pixel array 1510 to perform specific operations on the image pixels in the corresponding row based on commands and control signals supplied by the timing controller 1570. In an embodiment of the present disclosure, the row driver 1520 can select at least one image pixel arranged in at least one row of the pixel array 1510. The row driver 1520 can generate a row selection signal to select at least one row among the plurality of rows. The row driver 1520 can sequentially enable a pixel reset signal and a transmission signal for the image pixels corresponding to the selected at least one row. Accordingly, a reference signal and an image signal, each generated from the image pixels of the selected row, can be sequentially transmitted to the correlated double sampler 1530. Here, the reference signal is an electrical signal provided to the correlated double sampler 1530 when the sensing node (e.g., floating diffusion region) of the pixel is reset, and the image signal is an electrical signal provided to the correlated double sampler 1530 when the photocharges generated by the pixel are accumulated in the sensing node. The reference signal, which represents the pixel's inherent reset noise, and the image signal, which represents the intensity of incident light, can be collectively referred to as pixel signals.

The image sensing device 1500 can use correlated double sampling to sample the pixel signal twice in order to remove the difference between the two samples, thereby eliminating unwanted offset values, such as fixed pattern noise, from the image pixels. For example, correlated double sampling can remove unwanted offset values by comparing pixel output voltages obtained before and after photocharges generated by incident light are accumulated in the sensing node, allowing the measurement of pixel output voltage based solely on the incident light. In one embodiment of the present disclosure, the correlated double sampler 1530 can sequentially sample and hold the reference signal and the image signal provided to each of the plurality of column lines from the pixel array 1510. For example, the correlated double sampler 1530 can sample and hold the levels of the reference signal and the image signal corresponding to each column of the pixel array 1510.

The correlated double sampler 1530 can deliver the reference signal and the image signal of each column to the ADC 1540 as a correlated double sampling signal based on control signals from the timing controller 1570.

The ADC 1540 can convert the correlated double sampling signal for each column, output from the correlated double sampler 1530, into a digital signal and output image data. In an embodiment of the present disclosure, the ADC 1540 can convert and output the correlated double sampling signal generated by the correlated double sampler 1530 for each column into a digital signal.

The ADC 1540 can include a plurality of column counters corresponding to each column of the pixel array 1510. Each column of the pixel array 1510 is connected to a respective column counter, and image data can be generated by converting the correlated double sampling signal corresponding to each column into a digital signal using the column counters. In another embodiment of the present disclosure, the ADC 1540 can include a single global counter and convert the correlated double sampling signal corresponding to each column into a digital signal using a global code provided by the global counter.

The output buffer 1550 can temporarily hold and output image data for each column provided by the ADC 1540. Based on control signals from the timing controller 1570, the output buffer 1550 can temporarily store image data output from the ADC 1540. The output buffer 1550 can function as an interface that compensates for differences in transmission speed (or processing speed) between the image sensing device 1500 and other connected devices.

The column driver 1560 can select columns of the output buffer 1550 based on control signals from the timing controller 1570 and control the output buffer 1550 so that the temporarily stored image data in the selected column is sequentially output. In an embodiment of the present disclosure, the column driver 1560 can receive an address signal from the timing controller 1570, and based on the address signal, the column driver 1560 generates a column selection signal to select a column of the output buffer 1550, thereby controlling the image data to be output from the selected column of the output buffer 1550 to the outside.

The timing controller 1570 can control at least one of the row driver 1520, the correlate double sampler 1530, the ADC 1540, the output buffer 1550, and the column driver 1560.

The timing controller 1570 can provide clock signals, control signals for timing control, and address signals for selecting rows or columns to at least one of the row driver 1520, the correlate double sampler 1530, the ADC 1540, the output buffer 1550, and the column driver 1560, based on the required operation of each component of the image sensing device 1500. In an embodiment of the present disclosure, the timing controller 1570 can include a logic control circuit, a phase-locked loop (PLL) circuit, a timing control circuit, and a communication interface circuit.

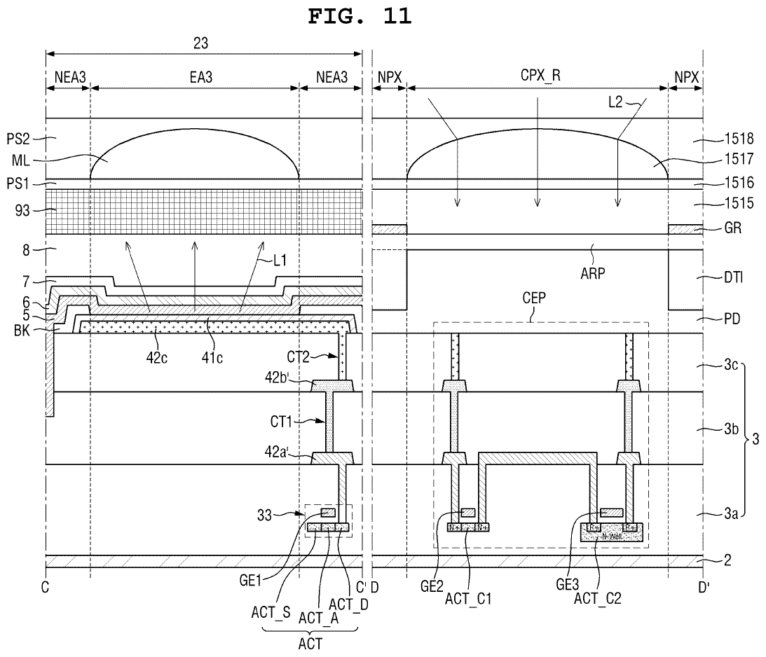

FIG. 11 is a cross-sectional view taken along C-C′ of FIG. 2 and D-D′ lines of FIG. 8. Referring to FIG. 11, the cross-sectional views of the display panel in FIGS. 4 and 5, along with the image sensing device, are shown. In FIG. 11, only the third panel sub-pixel 23 from FIGS. 4 and 5 is shown.

Referring to FIGS. 4, 5, and 11, the display panel and image sensing device include a substrate 2. The display panel and the image sensing device can share the substrate 2.

An insulating layer 3 can be disposed on the substrate 2 of the display panel and the image sensing device. Within the insulating layer 3 of the display panel, thin-film transistors, connecting electrodes, or reflective electrodes as described in FIGS. 4 and 5 can be arranged, while within the insulating layer 3 of the image sensing device, a circuit part CEP can be arranged. The circuit part CEP can include at least one thin-film transistor, image connection electrodes, etc. The circuit part CEP can be electrically connected to the photoelectric conversion device PD.

Within the first insulating layer 3a of the display panel, a third thin-film transistor 33 can be disposed, and within the first insulating layer 3a of the image sensing device, a thin-film transistor of the image sensing device can be disposed. For example, the third thin-film transistor 33 can include at least one of the switching thin-film transistor, driving thin-film transistor, and sensing thin-film transistor mentioned earlier. For example, the third thin-film transistor 33 can include a panel semiconductor layer ACT including a source region ACT_S, active region ACT_A, and drain region ACT_D, and a panel gate electrode GE1 overlapping the active region ACT_A.

The thin-film transistors of the image sensing device can include at least one of a row selection transistor, a pixel reset transistor, or a transfer transistor. For example, one of the thin-film transistors of the image sensing device can include a first image semiconductor layer ACT_C1 and a first image gate electrode GE2 on the first image semiconductor layer ACT_C1, while another one of the thin-film transistors of the image sensing device can include a second image semiconductor layer ACT_C2 and a second image gate electrode GE3 on the second image semiconductor layer ACT_C2.

In the electronic device according to an embodiment of the present disclosure, the third thin-film transistor 33 and the thin-film transistor of the image sensing device are located in the same layer and can be formed through the same process.

On the first insulating layer 3a of the display panel, the first connection electrode 42a′ is disposed, and the first connection electrode 42a′ can be electrically connected to the panel semiconductor layer ACT. On the first insulating layer 3a of the image sensing device, first image connection electrodes can be disposed, being connected to or connecting adjacent thin-film transistors of the image sensing device. The first connection electrode 42a′ on the first insulating layer 3a and the first image connection electrodes are located in the same layer and can be formed through the same process.

On the second insulating layer 3b of the display panel, the second connection electrode 42b′ is disposed, and the second connection electrode 42b′ can be connected to the first connection electrode 42a′ through the first contact hole CT1. On the second insulating layer 3b of the image sensing device, second image connection electrodes, which are connected to the first image connection electrodes, can be disposed. The second connection electrode 42b′ and the second image connection electrodes on the second insulating layer 3b are located in the same layer and can be formed through the same process.

On the third insulating layer 3c of the display panel, the third reflective electrode 42c is disposed, and the third reflective electrode 42c can be connected to the second connection electrode 42b′ through the second contact hole CT2. On the third insulating layer 3c of the image sensing device, third image connection electrodes, which are connected to the second image connection electrodes, can be disposed. The second contact hole CT2 and the third image connection electrode within the third insulating layer 3c can located in the same layer and can be formed through the same process.

On the third reflective electrode 42c of the display panel, the third anode electrode 41c, the common light-emitting layer 5, the cathode electrode 6, the capping layer 7, and the encapsulation layer 8 can be disposed. A first light L1 can be emitted upwards from the common light-emitting layer 5.

A photoelectric conversion device PD can be disposed on the circuit section CEP and the insulating layer 3 of the image sensing device. The photoelectric conversion device PD can include a photodiode, but the embodiments of the present disclosure are not limited thereto.

The photoelectric conversion device PD can include a single crystal silicon wafer or an epitaxially grown single crystal silicon layer. The photoelectric conversion device PD can have a high refractive index. For example, the refractive index of the photoelectric conversion device PD can be around 2.5 or higher, but this is not limiting. For example, the refractive index of the photoelectric conversion device PD can be between approximately 4 and 6, but this is not limiting.

The photoelectric conversion device PD can be formed by injecting P-type and N-type ions. P-type ions can include boron (B) ions, and N-type ions can include phosphorous (P) and/or arsenic (As) ions. The photoelectric conversion device PD plays a role in receiving incident light and converting the optical signal into an electrical signal.

A peripheral region NPX of the photoelectric conversion device PD can include a trench DTI. The trench DTI can be formed through the Deep Trench process. The trench DTI can include an insulating material. For example, insulating materials can include hafnium oxide (HfO2) or silicon oxide (SiO2), but are not limited thereto. The refractive index of the trench DTI may, for example, range from about 1.4 to about 2.0, but is not limited thereto. The trench DTI can serve to totally reflect the light incident on the trench DTI towards the photoelectric conversion device PD. The trench DTI can either totally reflect or scatter the light towards the photoelectric conversion device PD, thus increasing the light's path. As a result, the trench DTI can enhance the photoelectric conversion efficiency of the photoelectric conversion device PD.

An anti-reflective layer ARP can be disposed on the photoelectric conversion device PD and the trench DTI. The anti-reflective layer ARP can be in direct contact with the trench DTI and the photoelectric conversion device PD. The anti-reflective layer ARP can include the same material as the trench DTI. The anti-reflective layer ARP can be formed in the same process as the trench DTI and can be integrally connected to the trench DTI. The anti-reflective layer ARP can serve to prevent or reduce total reflection of light incident from the light-concentrating pattern MLP at the photoelectric conversion device PD. To this end, the anti-reflective layer ARP can have a refractive index between the refractive index of the color filter CF_R, CF_G and the refractive index of the photoelectric conversion device PD, or between the refractive index of the scattering portion SP and the refractive index of the photoelectric conversion device PD, but is not limited thereto. For example, the refractive index of the anti-reflective layer ARP can range from about 1.4 to about 2.0, but is not limited thereto.

A grid region GR can be disposed on the anti-reflective layer ARP. The grid region GR can be arranged in the peripheral region NPX. The grid region GR can include a metal or air structure, but the embodiments of the present disclosure are not limited thereto. The grid region GR can prevent or reduce optical color mixing between adjacent pixel regions.

A color filter (a third panel color filter 93 in FIG. 11) can be disposed on the encapsulation layer 8 of the display panel. A third image color filter 1515 can be disposed on the anti-reflective layer ARP and the grid region GR of the image sensing device. The third image color filter 1515 of the red pixel region CPX_R in FIG. 11 can function as a red color filter. The third panel color filter 93 and the red color filter of the image sensing device can be disposed in the same layer and formed through the same process.

A first passivation layer PS1 can be disposed on the third panel color filter 93, a panel light-concentrating pattern ML can be disposed on the first passivation layer PS1, and a second passivation layer PS2 can be disposed on the panel light-concentrating pattern ML. A third passivation layer 1516 can be disposed on the third image color filter, an image light-concentrating pattern 1517 can be disposed on the third passivation layer 1516, and a fourth passivation layer 1518 can be disposed on the image light-concentrating pattern 1517. The first passivation layer PS1 and the third passivation layer 1516 can be located in the same layer and formed through the same process. The second passivation layer PS2 and the fourth passivation layer 1518 can be located in the same layer and formed through the same process. The panel light-concentrating pattern ML and the image light-concentrating pattern 1517 can be located in the same layer and formed through the same process.

A second light L2 can be received through the image light-concentrating pattern 1517 of the image sensing device. The second light L2 refers to light in the visible wavelength range.

Hereinafter, an electronic device according to another embodiment of the present disclosure will be described. In explaining the following embodiments of the present disclosure, detailed descriptions of configurations that are the same as or similar to those described with reference to FIGS. 1 to 11 will be omitted to avoid redundancy.

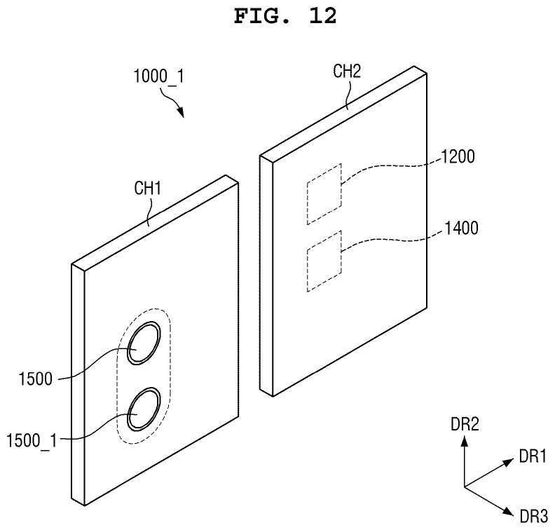

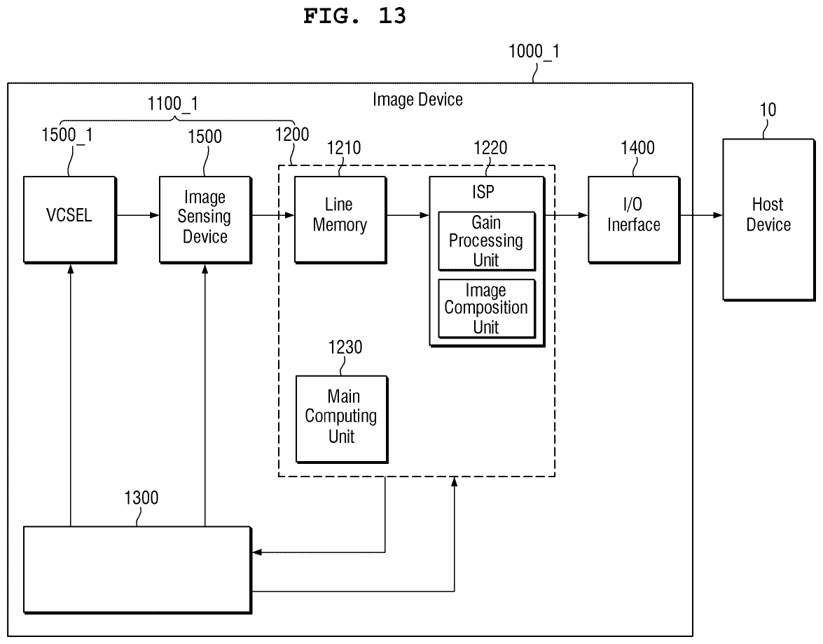

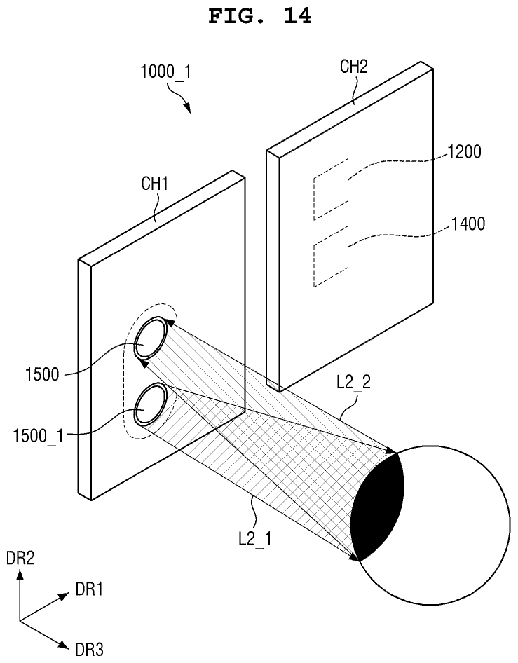

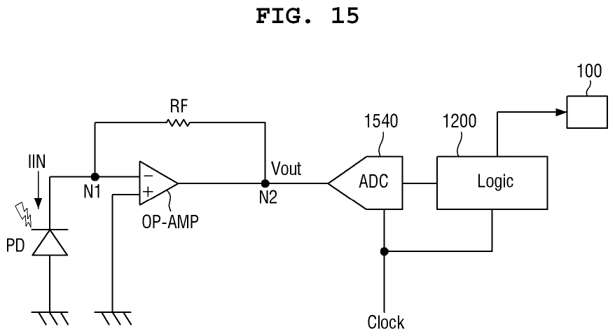

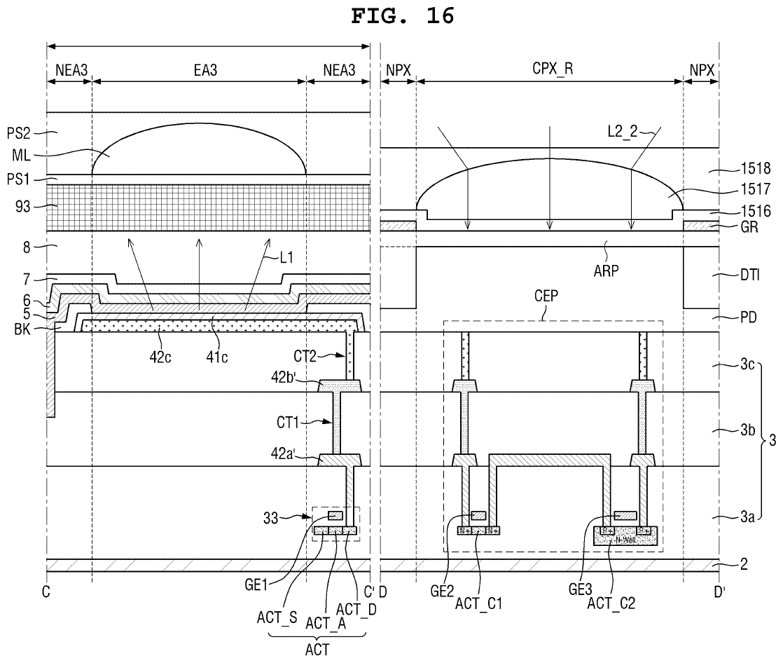

FIG. 12 is a perspective view of the optical device according to another embodiment of the present disclosure. FIG. 13 is a detailed view of the optical device of FIG. 12. FIG. 14 is a schematic diagram illustrating the generation of user gaze position data through the optical device according to another embodiment of the present disclosure. FIG. 15 is a schematic diagram illustrating the generation and provision of user gaze position data according to another embodiment of the present disclosure. FIG. 16 is a cross-sectional view of the display panel and image sensing device of the electronic device according to another embodiment of the present disclosure.

The optical device 1000_1 according to the embodiment of FIGS. 12 to 16 differs from the optical device 1000 according to the embodiment of FIGS. 8 to 11 in that the optical device 1000_1 irradiates infrared or near-infrared light onto the subject and receives the reflected infrared or near-infrared light from the subject.

More specifically, the optical device 1000_1 can further include a light-emitting unit 1500_1. The imaging device 1100_1 of the optical device 1000_1 can further include the light-emitting unit 1500_1, which can be a vertical cavity surface emitting laser (VCSEL), but the embodiments of the present disclosure are not limited thereto. The light-emitting unit 1500_1 can irradiate infrared (or near-infrared) light onto the subject. The image sensing device 1500 can serve to receive the reflected light from the subject, which was irradiated by the light-emitting unit 1500_1. The light-emitting unit 1500_1 can irradiate infrared light (or near-infrared light) onto the subject in the form of a laser.

As shown in FIG. 14, the light-emitting unit 1500_1 can irradiate infrared or near-infrared light L2_1 onto a subject (the user's pupil in FIG. 14), and the image sensing device 1500 can receive the light L2_2 reflected from the subject. For example, the optical device 1000_1 according to this embodiment can have an eye-tracking function for detecting the user's pupil position and gaze position. The optical device 1000_1 can calculate the coordinates of the user's actual gaze position based on the detected pupil position data and gaze position data.

As shown in FIG. 15, the photoelectric conversion device PD can receive light (infrared or near-infrared light L2_2 in FIG. 14). A photocurrent IIN is generated in proportion to the amount of light received by the photoelectric conversion device PD, and a photovoltage corresponding to the photocurrent IIN is applied to the first node N1. The photovoltage is applied to the (−) terminal of the OP-AMP, while the (+) terminal of the OP-AMP is connected to the ground voltage. Through the OP-AMP and the amplification resistor RF, the photovoltage is amplified, and the amplified output voltage VOUT is output at the second node N2, which is the output terminal of the OP-AMP. The output voltage VOUT is converted from an analog output voltage to a digital output voltage value through an analog-to-digital converter (ADC) 1540. The output voltage value is provided to the logic unit 1200. The main computing unit 1230 (FIG. 9) of the logic unit 1200 processes the output voltage value based on the clock signal to generate the user's pupil position data and gaze position data and transmits the data to the display panel 100 of the display device. The timing controller TC (FIG. 1) of the display panel 100 can control the brightness of each panel pixel of the display panel 100 based on the received pupil position data and gaze position data, thereby adjusting the brightness of the display panel 100.

As shown in FIG. 16, the image sensing device according to this embodiment may not include a color filter. For example, the image sensing device in FIG. 16 may not include the third image color filter.

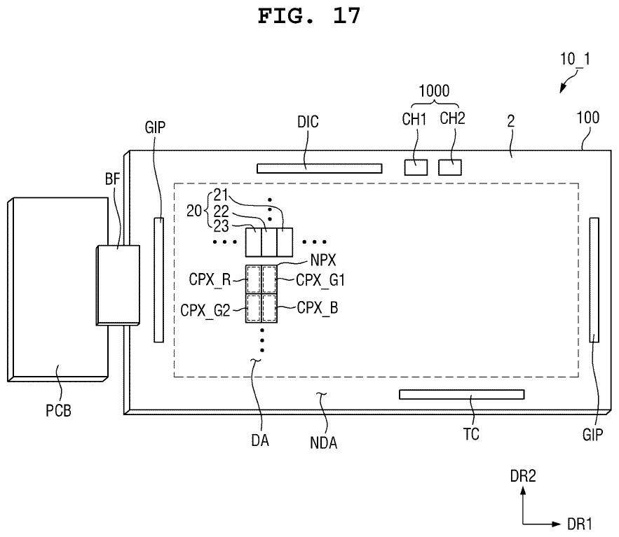

FIG. 17 is a plan view of the electronic device according to another embodiment of the present disclosure.

The electronic device 10_1 according to the embodiment of FIG. 17 differs from the electronic device 10 according to the embodiment of FIG. 2 in that the image pixels of the optical device are arranged within the display area DA.

For example, an image pixel can be arranged adjacent to any one of the panel pixels 20. The panel pixel 20 and the image pixel form a group, and the panel pixels 20 and image pixels forming the group can be repeatedly arranged in the display area DA.

According to this embodiment, the image sensing device of the optical device can be arranged in the display area DA, and the second chip CH2 of the optical device can be arranged in the non-display area NDA. In some embodiments of the present disclosure, the second chip CH2 can also be arranged in the display area DA.

Other explanations are omitted as they have been detailed above with reference to FIG. 2.

The electronic device according to various embodiments of the present disclosure can be described as follows.

An electronic device according to various embodiments of the present disclosure includes a substrate including a display area including display pixels and a non-display area surrounding the display area, a display panel including an organic light-emitting device arranged in the display pixels of the substrate, and an optical device including an image sensing device mounted on the substrate, the image sensing device being configured to receive light and generate image data, and a logic unit operably connected to the image sensing device.

In the electronic device according to various embodiments of the present disclosure, the optical device can be arranged in the non-display area.

In the display device according to various embodiments of the present disclosure, the image sensing device can be configured to receive visible light.

In the electronic device according to various embodiments of the present disclosure, the logic unit can include a line memory configured to receive and store the image data, and an image signal processor configured to receive the stored image data from the line memory and perform image signal processing.

In the electronic device according to various embodiments of the present disclosure, the display pixels can include an emissive area and a non-emissive area located around the emissive area, and the display panel can include a first insulating layer on the substrate and a panel transistor in the non-emissive area within the first insulating layer.

In the electronic device according to various embodiments of the present disclosure, the image sensing device can include image pixels, each of which can include an image pixel region and an image peripheral region surrounding the image pixel region, and a circuit part on the substrate, the circuit part including a first insulating layer and an image transistor within the first insulating layer.

In the electronic device according to various embodiments of the present disclosure, the organic light-emitting device can include an anode electrode and a panel connection electrode or a reflective electrode connecting the panel transistor and the anode electrode.

In the electronic device according to various embodiments of the present disclosure, the image sensing device can further include a photoelectric conversion device in the image pixel region on the circuit part, and the circuit part further can include an image connection electrode connecting the image transistor and the photoelectric conversion element, wherein the image connection electrode can be disposed on the same layer as a panel connection electrode or a reflective electrode.

In the electronic device according to various embodiments of the present disclosure, the organic light-emitting device can further include a common light-emitting layer on the anode electrode and a cathode electrode on the common light-emitting layer, and the display panel can further include a panel color filter on the cathode electrode.

In the electronic device according to various embodiments of the present disclosure, the image sensing device can further include an image color filter on the photoelectric conversion device, and the image color filter and the panel color filter can be located in the same layer.

In the electronic device according to various embodiments of the present disclosure, the optical device can further include a light-emitting unit configured to irradiate light onto the subject.

In the electronic device according to various embodiments of the present disclosure, the image sensing device can be configured to receive light reflected from the subject, the light being irradiated by the light-emitting unit.

In the electronic device according to various embodiments of the present disclosure, the light-emitting unit can irradiate infrared light or near-infrared light onto the subject.

In the electronic device according to various embodiments of the present disclosure, the image sensing device can be arranged in the display area.

In the electronic device according to various embodiments of the present disclosure, the display panel can include a data driver, a gate driver, and a timing controller, and the data driver, the gate driver, and the timing controller can be mounted on the substrate.

An electronic device according to various embodiments of the present disclosure includes a substrate including a display area including display pixels and a non-display area surrounding the display area, a display panel including an organic light-emitting device arranged on the substrate, and an optical device including a first chip including an image sensing device configured to receive light and generate image data, and a second chip operably connected to the image sensing device and distinct from the first chip, wherein the first chip and the second chip are each mounted on the substrate.

In the electronic device according to various embodiments of the present disclosure, the first chip and the second chip can each be arranged in the non-display area.

In the electronic device according to various embodiments of the present disclosure, the first chip can be arranged in the display area, and the second chip can be arranged in the non-display area.

In the electronic device according to various embodiments of the present disclosure, the optical device can further include a light-emitting unit configured to irradiate light onto a subject, the image sensing device can be configured to receive light reflected from the subject, the light being irradiated by the light-emitting unit, and the light-emitting unit can irradiate infrared light or near-infrared light onto the subject.

In the electronic device according to various embodiments of the present disclosure, the display panel can include a data driver, a gate driver, and a timing controller, and the data driver, the gate driver, and the timing controller can be mounted on the substrate.

According to embodiments of the present disclosure, an organic light-emitting device and an optical device can be arranged on a substrate. The optical device can include an image sensing device that generates image data and a logic unit operably coupled to the image sensing device. The image sensing device can be included in a first chip, and the logic unit can be included in a second chip. The first chip and the second chip can each be mounted on the substrate. This is advantageous for achieving a compact electronic device.

According to embodiments of the present disclosure, mounting the first chip and the second chip on the substrate helps reduce the number of components in the electronic device.

According to embodiments of the present disclosure, the optical device can further include a light-emitting unit that emits infrared light or near-infrared light toward a subject, and the image sensing device can receive light emitted from the light-emitting unit and reflected by the subject. For example, the image sensing device can operate as a distance sensor. The optical device can generate gaze position data of a user, and the display panel can control brightness based on the gaze position data.

According to embodiments of the present disclosure, since the display panel controls brightness based on the gaze position data, a low-power electronic device can be achieved.

However, the effects achievable by aspects of the present disclosure are not limited to the aforementioned, and additional effects not explicitly described herein can be readily understood by those skilled in the art based on the disclosure.

Although the embodiments of the present disclosure have been described with reference to the attached drawings, it will be understood by those skilled in the art that the described technical configurations can be implemented in other specific forms without altering the technical essence or essential features. Therefore, it should be understood that the embodiments described above are examples and not limited in all respects. Moreover, the scope of the embodiments of the present disclosure is determined by the claims that follow, rather than by the detailed description. Any modifications or variations derived from the meaning, scope, and equivalent concepts of the patent claims are to be considered as falling within the scope of the embodiments of the present disclosure.

### DESCRIPTION OF REFERENCE NUMERALS

10: electronic device
100: display panel
1000: optical device

What is claimed is:

1. An electronic device comprising:
a substrate comprising a display area including display pixels and a non-display area adjacent to the display area;
a display panel comprising an organic light-emitting device arranged in the display pixels of the substrate; and
an optical device comprising an image sensing device mounted on the substrate and a logic unit operably connected to the image sensing device, the image sensing device being configured to receive light and generate image data.

2. The electronic device of claim 1, wherein the optical device is arranged in the non-display area.

3. The electronic device of claim 1, wherein the image sensing device is configured to receive visible light.

4. The electronic device of claim 1, wherein the logic unit comprises:
a line memory configured to receive and store the image data; and
an image signal processor configured to receive the stored image data from the line memory and perform image signal processing.

5. The electronic device of claim 1, wherein the display pixels comprise an emissive area and a non-emissive area located around the emissive area, and
wherein the display panel comprises a first insulating layer on the substrate and a panel transistor in the non-emissive area within the first insulating layer.

6. The electronic device of claim 5, wherein the image sensing device comprises:
image pixels, each of the image pixel including an image pixel region and an image peripheral region surrounding the image pixel region; and
a circuit part on the substrate, the circuit part comprising a first insulating layer and an image transistor within the first insulating layer.

7. The electronic device of claim 6, wherein the organic light-emitting device comprises an anode electrode and a panel connection electrode, or comprises the anode electrode and a reflective electrode connecting the panel transistor and the anode electrode.

8. The electronic device of claim 7, wherein the image sensing device further comprises a photoelectric conversion device in the image pixel region on the circuit part,
wherein the circuit part further comprises an image connection electrode connecting the image transistor and the photoelectric conversion element, and
wherein the image connection electrode is disposed on a same layer as a panel connection electrode or a reflective electrode.

9. The electronic device of claim 8, wherein the organic light-emitting device further comprises a common light-emitting layer on the anode electrode and a cathode electrode on the common light-emitting layer, and
wherein the display panel further comprises a panel color filter on the cathode electrode.

10. The electronic device of claim 9, wherein the image sensing device further comprises an image color filter on the photoelectric conversion device, and the image color filter and the panel color filter are located in a same layer.

11. The electronic device of claim 1, wherein the optical device further comprises a light-emitting unit configured to irradiate light onto a subject.

12. The electronic device of claim 11, wherein the image sensing device is configured to receive light reflected from the subject, the light being irradiated by the light-emitting unit.

13. The electronic device of claim 12, wherein the light-emitting unit irradiates infrared light or near-infrared light onto the subject.

14. The electronic device of claim 1, wherein the image sensing device is arranged in the display area.

15. The electronic device of claim 1, wherein the display panel comprises a data driver, a gate driver, and a timing controller, and
wherein the data driver, the gate driver, and the timing controller are mounted on the substrate.

16. An electronic device comprising:
a substrate comprising a display area and a non-display area adjacent to the display area;
a display panel comprising an organic light-emitting device arranged on the substrate; and
an optical device comprising a first chip including an image sensing device configured to receive light and generate image data, and a second chip operably connected to the image sensing device and distinct from the first chip,
wherein the first chip and the second chip are separately mounted on the substrate.

17. The electronic device of claim 16, wherein the first chip and the second chip are separately arranged in the non-display area.

18. The electronic device of claim 16, wherein the first chip is arranged in the display area, and the second chip is arranged in the non-display area.

19. The electronic device of claim 16, wherein the optical device further comprises a light-emitting unit configured to irradiate light onto a subject,
wherein the image sensing device is configured to receive light reflected from the subject, the light being irradiated by the light-emitting unit, and
wherein the light-emitting unit irradiates infrared light or near-infrared light onto the subject.

20. The electronic device of claim 16, wherein the display panel comprises a data driver, a gate driver, and a timing controller, and
wherein the data driver, the gate driver, and the timing controller are mounted on the substrate.
